(19) United States
(12) Patent Application Publication
(10) Pub. No.: US 2024/0234288 A1
(43) Pub. Date: Jul. 11, 2024

(54) SEMICONDUCTOR PACKAGE

(71) Applicant: JMJ Korea Co., Ltd., Busan (KR)

(72) Inventor: Yun Hwa CHOI, Busan (KR)

(73) Assignee: JMJ Korea Co., Ltd., Busan (KR)

(21) Appl. No.: 18/384,386

(22) Filed: Oct. 27, 2023

(30) Foreign Application Priority Data
Jan. 6, 2023 (KR) 10-2023-0002256

(51) Int. Cl. H01L 23/498; H01L 23/00; H01L 23/31; H01L 25/065

(52) U.S. Cl. CPC H01L 23/49838; H01L 23/3107; H01L 23/49811; H01L 24/13; H01L 24/16; H01L 24/73; H01L 25/0655; H01L 24/48; H01L 2224/1012; H01L 2224/13017; H01L 2224/13083; H01L 2224/16227; H01L 2224/16238; H01L 2224/48225; H01L 2224/73207; H01L 2924/3512

(57) ABSTRACT

Provided is a semiconductor package, and more particularly, a semiconductor package in which a semiconductor device is protected in such a way that stress from push and thermal expansion generated while molding by a package housing is dispersed or absorbed through an electrical connecting member having a non-vertical structure bent in a z-letter shape.

### CROSS-REFERENCE TO RELATED PATENT APPLICATION

This application claims the benefit of Korean Patent Application No. 10-2023-0002256, filed on Jan. 6, 2023, in the Korean Intellectual Property Office, the disclosure of which is incorporated herein in its entirety by reference.

### BACKGROUND OF THE INVENTION

### Field of the Invention

The present invention relates to a semiconductor package, and more particularly, to a semiconductor package in which a semiconductor device is protected in such a way that stress from push and thermal expansion generated while molding by a package housing is dispersed or absorbed through an electrical connecting member having a non-vertical structure bent in a z-letter shape.

### Description of the Related Art

In general, a semiconductor package includes a semiconductor chip installed on a lower substrate or an upper substrate, a conductor which is a metal post functioning as a spacer adhered onto the semiconductor chip, a lead frame formed of Cu for applying an electrical signal from the outside, and a package housing molded by a sealing member. Here, the semiconductor chip is bonded onto a lead frame pad, and a lead frame lead is electrically connected to a pad of the semiconductor chip through a bonding wire, which is a signal line, by using a plating layer formed of Ag and interposed therebetween.

For example, as illustrated in a general semiconductor package of FIG. 1A, a semiconductor chip 14 is bonded on a lower metal insulating substrate 11A by using a first bonding member 12 interposed therebetween, a hexahedral or cylindrical conductor 17 which is a metal spacer having a vertical structure is bonded onto the semiconductor chip 14 by using a second bonding member 16 and is bonded onto an upper metal insulating substrate 11B by using a third bonding member 13, and a metal bridge 18 having a vertical structure is formed between the lower metal insulating substrate 11A and the upper metal insulating substrate 11B so as to be electrically connected to each other.

A semiconductor chip is bonded to a substrate and a conductor by using a solder, however, a crack is generated in the first bonding member 12 or the second bonding member 16 as illustrated in FIG. 1B due to a different Coefficient of Thermal Expansion (CTE) between the substrates 11A and 11B, the conductor 17, the first bonding member 12, and the second bonding member 16. Accordingly, a reliability issue is generated.

That is, a main cause of a crack in the bonding members due to a CTE difference is attributed to a direct shock to a semiconductor chip generated by pressurizing an upper insulating substrate and a metal spacer by a mold when the metal spacer bonded to the surface of the semiconductor chip is directly and vertically bonded to the upper insulating substrate and molding is executed to form a package housing. In this regard, the yield of products may be lowered.

Meanwhile, in order to minimize a CTE difference with a semiconductor chip, a metal spacer or a metal post may be replaced with a material similar to a CTE of the semiconductor chip, however, such material is considerably expensive compared with an existing metal spacer or metal post. Accordingly, price competitiveness of products is lowered.

### SUMMARY OF THE INVENTION

The present invention provides a semiconductor package in which a semiconductor device is protected in such a way that stress from push and thermal expansion generated while molding by a package housing is dispersed or absorbed through an electrical connecting member having a non-vertical structure bent in a z-letter shape.

According to an aspect of the present invention, there is provided a semiconductor package including: a first substrate including a specific metal pattern formed thereon to enable electrical connection; a second substrate facing the first substrate which is spaced apart from the first substrate and includes a specific metal pattern formed thereon to enable electrical connection; at least one semiconductor chip in which one surface thereof is bonded to the first substrate, the second substrate, or the first and second substrates by using a first bonding member interposed therebetween; at least one electrical connecting member including a first metal piece formed in a straight line, a second metal piece which faces the first metal piece and is formed in a straight line, and a third metal piece which is extended by being bent from one side of the first metal piece to the other end of the second metal piece and is combined to the first metal piece and the second metal piece, wherein the first metal piece is bonded to the other surface of the semiconductor chip by using a second bonding member interposed therebetween and the third metal piece is bonded to each of the second substrate, the first substrate, or the first and second substrates; a package housing molded to cover the entire semiconductor chip and at least a part of the electrical connecting members; and at least one terminal electrically connected to the first substrate or the second substrate and exposed to the outside of the package housing, wherein a first acute angle between the first metal piece and the third metal piece and a second acute angle between the third metal piece and the second metal piece are each formed by being bent to be 1° through 85°.

Here, the first substrate or the second substrate may include at least one insulating layer.

Also, the first substrate or the second substrate may include a metal layer formed of a conductive metal material.

Also, the first substrate or the second substrate may include at least one metal layer, at least one insulating layer, and at least one metal layer which are stacked in order.

Here, the metal layer of the first substrate or the second substrate bonded to the first bonding member may have a thickness of 10 μm through 1.5 mm.

Also, the electrical connecting member may have a thickness of 0.1 mm through 1.5 mm.

Also, the electrical connecting member may have thermal conductivity of 150 W/(m-k) through 550 W/(m-k).

Also, the electrical connecting member may contain at least copper component.

Also, the first bonding member or the second bonding member may contain at least any one of Ag, Cu, and Sn.

The third metal piece of the electrical connecting member may be structurally connected to the right end part of the first metal piece and the left end part of the second metal piece.

Also, the third metal piece of the electrical connecting member may be structurally connected to the left end part of the first metal piece and the right end part of the second metal piece.

Also, the third metal piece of the electrical connecting member may be structurally connected between the first metal piece and the second metal piece in a diagonal direction.

Also, the semiconductor package may further include additional electrical connecting members structurally connected to the first substrate and the second substrate.

Here, the additional electrical connecting member may be structurally connected to the first substrate and the second substrate by using a conductive bonding member or directly bonded to the first substrate and the second substrate by ultrasonic welding, or the additional electrical connecting member may be structurally connected to the first substrate and the second substrate by using a conductive bonding member and directly bonded to the first substrate and the second substrate by ultrasonic welding.

Also, one end of the terminal may be electrically connected to each of the first substrate, the second substrate, or the first and second substrates within the package housing.

Also, the first substrate, the second substrate, or at least a part of the first and second substrates may be exposed from the package housing.

Also, a thickness of the first metal piece in the electrical connecting member bonded to the semiconductor chip may be greater than a thickness of the insulating layer of the first substrate or the second substrate.

Also, at least any one of the first substrate and the second substrate may include at least one radiation fin structurally exposed.

Also, the semiconductor chip may be an Insulated Gate Bipolar Transistor (IGBT), a diode, a Metal-Oxide-Semiconductor Field-Effect Transistor (MOSFET), or a Junction Field Effect Transistor (JFET).

According to another aspect of the present invention, there is provided a power converting device such as an inverter, a converter, or an on board charger (OBC) which uses the semiconductor package described above.

### BRIEF DESCRIPTION OF THE DRAWINGS

The above and other features and advantages of the present invention will become more apparent by describing in detail exemplary embodiments thereof with reference to the attached drawings in which:

FIGS. 1A and 1B illustrate a semiconductor package according to a conventional art;

FIG. 2 illustrates a first example of a semiconductor package according to an embodiment of the present invention;

FIGS. 3A, 3B and 3C are an exploded view of an electrical connecting member of the semiconductor package of FIG. 2;

FIG. 4 illustrates a second example of a semiconductor package according to an embodiment of the present invention;

FIG. 5 illustrates a third example of a semiconductor package according to an embodiment of the present invention;

FIG. 6 illustrates a fourth example of a semiconductor package according to an embodiment of the present invention;

FIG. 7 illustrates a fifth example of a semiconductor package according to an embodiment of the present invention; and

FIGS. 8A and 8B illustrate a modification example of the electrical connecting member of FIGS. 3A, 3B and 3C.

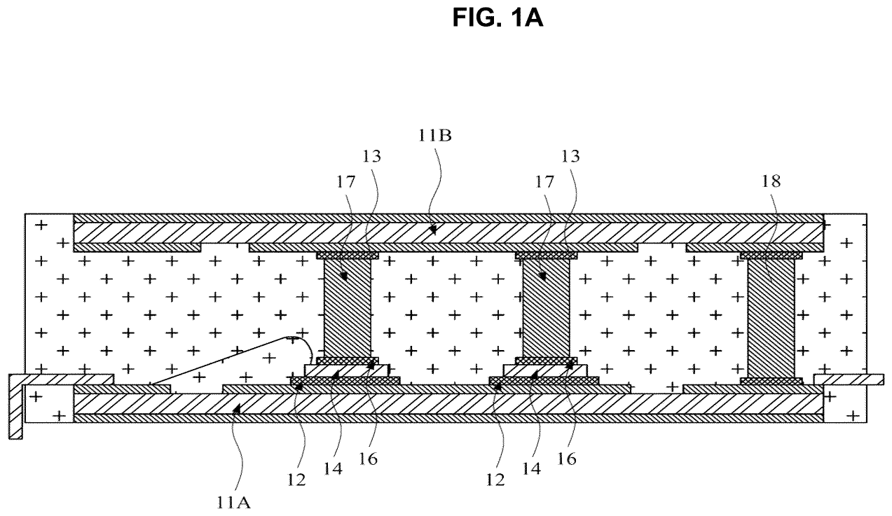

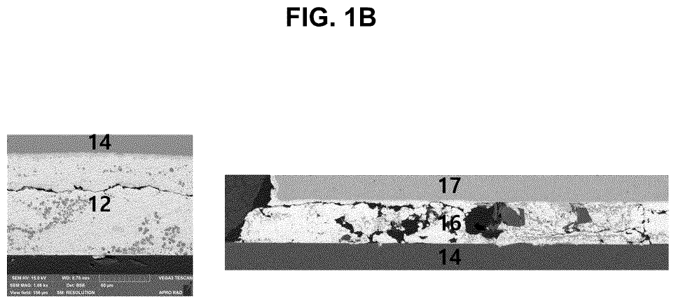

### DETAILED DESCRIPTION OF THE INVENTION

Hereinafter, embodiments of the present invention will be described in more detail with reference to the accompanying drawings.

A semiconductor package according to an embodiment of the present invention includes a first substrate 110, a second substrate 120, at least one semiconductor chip 130, at least one electrical connecting member 140 comprising a first metal piece 141 formed in a straight line, a second metal piece 142 which faces the first metal piece 141 and is formed in a straight line, and a third metal piece 143 which is extended by being bent from one side of the first metal piece 141 to the other end of the second metal piece 142 and is combined to the first metal piece 141 and the second metal piece 142, a package housing 150, and at least one terminal 160, wherein the first substrate 110 includes a specific metal pattern formed thereon to enable electrical connection, the second substrate 120 facing the first substrate 110 is spaced apart from the first substrate 110 and includes a specific metal pattern formed thereon to enable electrical connection, the at least one semiconductor chip 130 comprises one surfaces each bonded to the first substrate 110, the second substrate 120, or the first and second substrates 110 and 120 by using a bonding member 131 interposed therebetween, the first metal piece 141 is bonded to the other surface of the semiconductor chip 130 by using the bonding member 131 interposed therebetween and the third metal piece 143 is bonded to each of the second substrate 120, the first substrate 110, or the first and second substrates 110 and 120, the package housing 150 is molded to cover the entire semiconductor chip 130 and at least a part of the electrical connecting members 140, and the at least one terminal 160 is electrically connected to the first substrate 110 or the second substrate 120 and is exposed to the outside of the package housing 150. Here, a first acute angle α between the first metal piece 141 and the third metal piece 143 and a second acute angle β between the third metal piece 143 and the second metal piece 142 are each formed by being bent to be 1° through 85°. Accordingly, thermal expansion stress to the semiconductor chip 130 may be dispersed or absorbed through the bent electrical connecting member 140 while molding by the package housing 150.

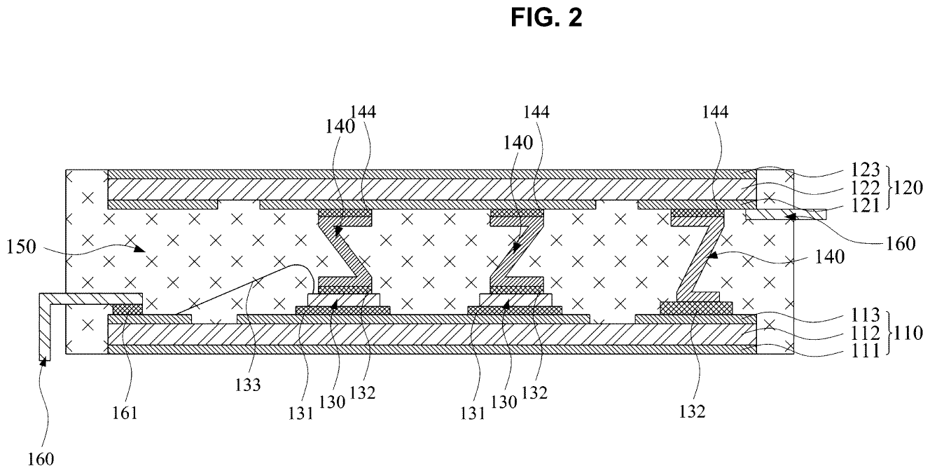

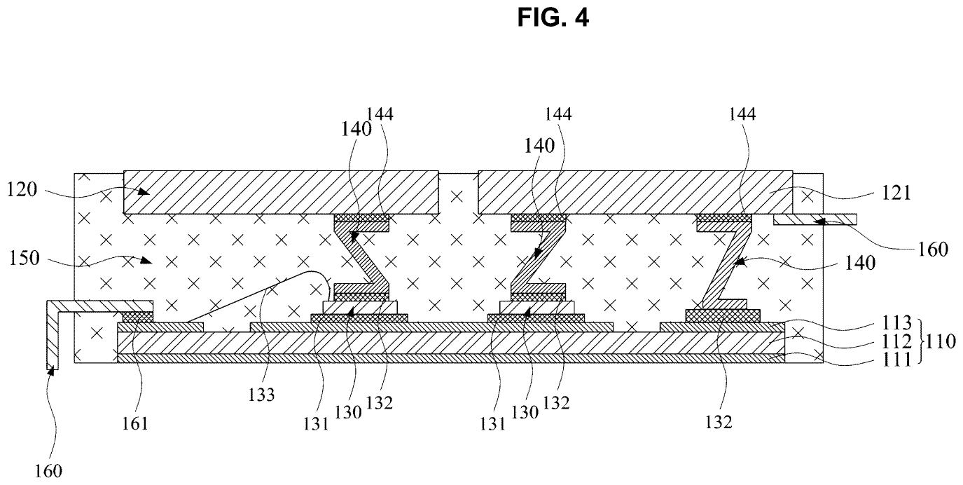

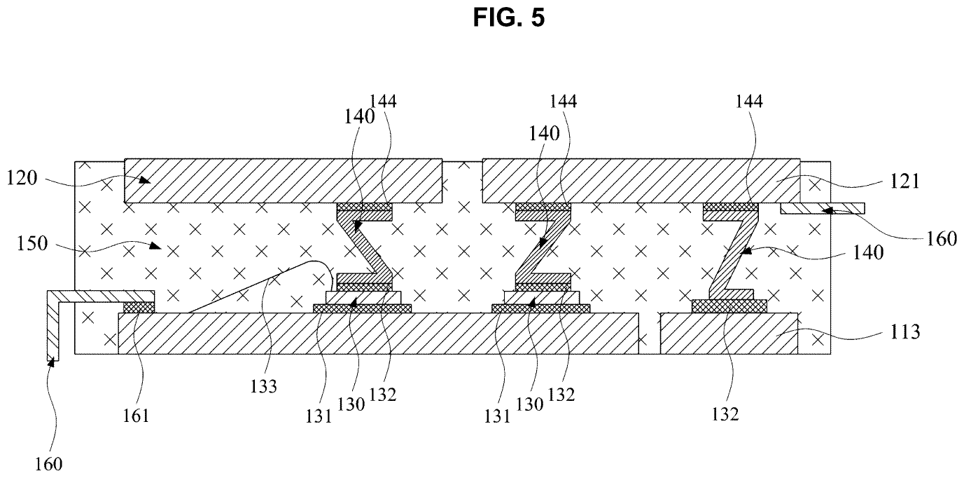

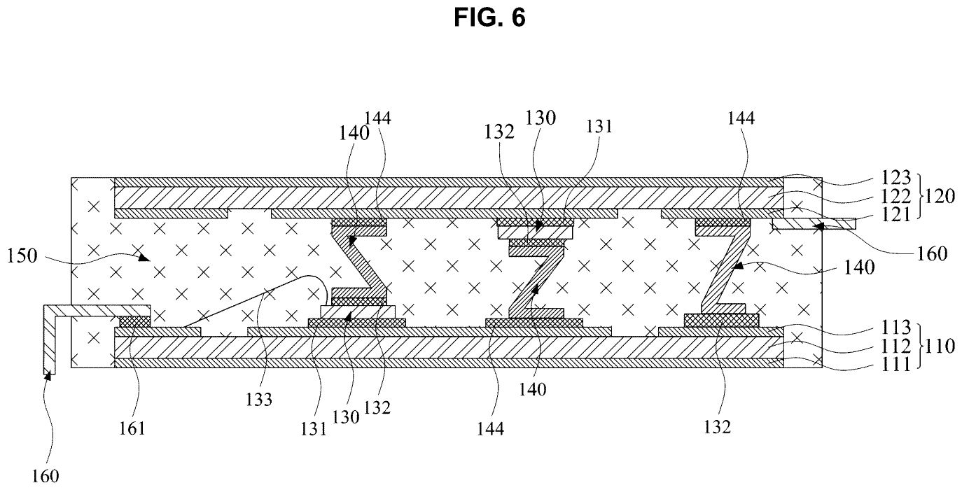

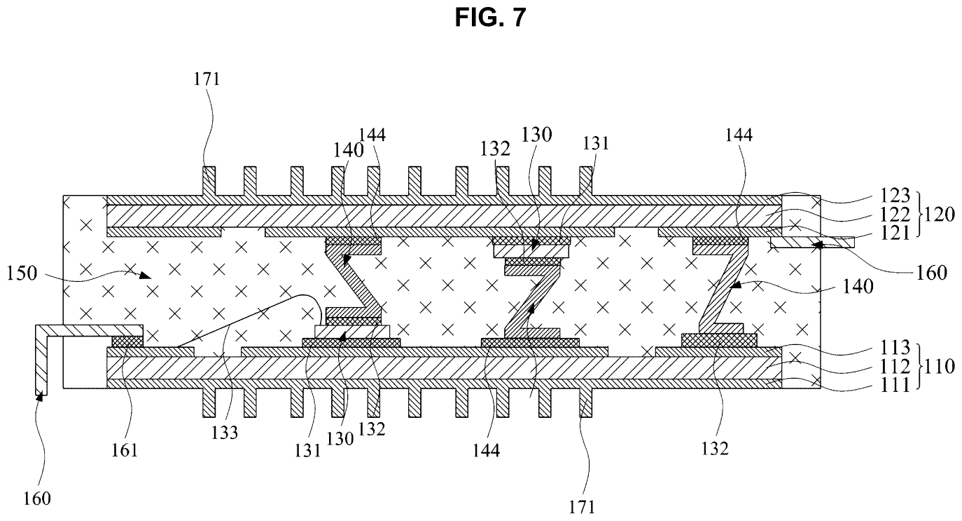

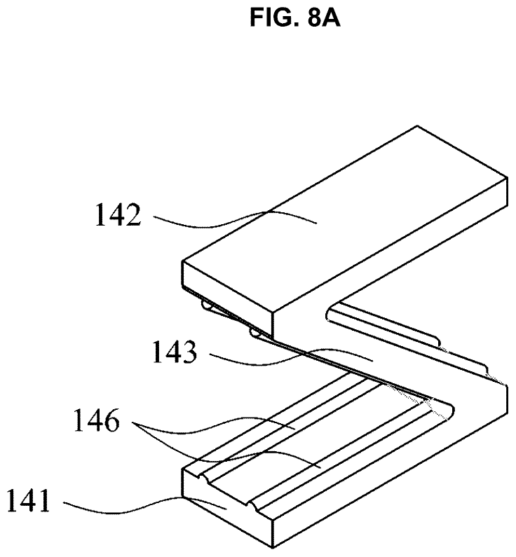

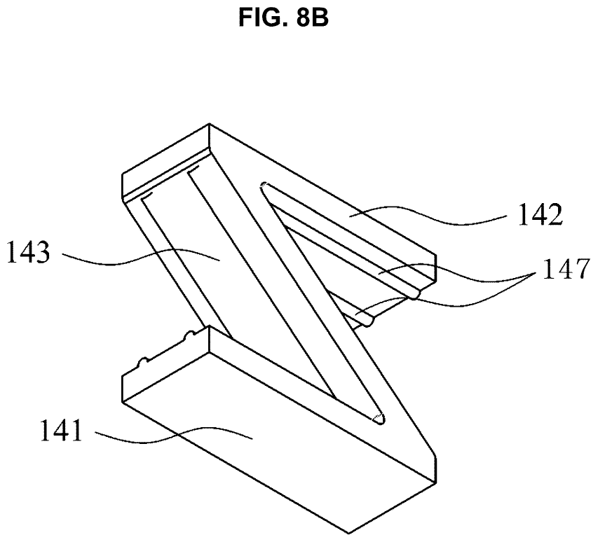

FIG. 2 illustrates that at least one insulating substrate is used and the semiconductor chips are disposed on one substrate, FIG. 4 illustrates that at least one metal substrate and at least one insulating substrate are used, FIG. 5 illustrates that at least one metal substrate is used, FIG. 6 illustrates that the semiconductor chips are each installed on the upper substrate and the lower substrate, FIG. 7 illustrates that a radiation fin is exposed to the substrate, and FIGS. 8A and 8B illustrate a modification example of the electrical connecting member.

Hereinafter, the semiconductor package above will be described in more detail with reference to FIGS. 2 through 8A and 8B.

First, the first substrate 110 is a lower substrate and includes a specific metal pattern formed thereon to enable electrical connection and at least one semiconductor chip 130 installed thereon.

Next, the second substrate 120 is an upper substrate which faces and is spaced apart from the first substrate 110 and includes a specific metal pattern formed thereon to enable electrical connection. At least one semiconductor chip 130 may be or may not be installed on the second substrate 120.

Here, referring to FIG. 2, the first substrate 110 or the second substrate 120 may include one or more insulating layers 112 and 122 formed of Al₂O₃ (ceramic) or AlN.

Also, the first substrate 110 or the second substrate 120 may include one or more metal layers 111, 121, 113, and 123 formed of a conductive metal material.

In addition, the substrate 110 or the second substrate 120 may have a stacked structure in which one or more metal layers 111 and 121, one or more insulating layers 112 and 122 formed of Al₂O₃ (ceramic) or AlN, and one or more metal layers 113 and 123 are stacked in order.

Furthermore, a thickness of the metal layers 113 and 121 bonded to the bonding member 131 on the first substrate 110 or the second substrate 120 may be 10 μm through 1.5 mm. Here, referring to FIGS. 4 and 5, the metal layers 121 and 113 may each be a single metal layer, an alloy metal layer, or a plated metal layer.

Next, more than one semiconductor chip 130 is included, wherein one surface of the semiconductor chip 130 may be bonded to the first substrate 110 (refer to FIGS. 2, 4 and 5), the second substrate 120 (not illustrated), or the first substrate 110 and the second substrate 120 (refer to FIGS. 6 and 7) by using the bonding member 131 interposed therebetween, and the other surface of the semiconductor chip 130 may be bonded to the electrical connecting member 140 by using the bonding member 132 interposed therebetween and may be electrically connected to the corresponding substrate through a wire bonding 133 or a clip structure (not illustrated).

The semiconductor chip is a power semiconductor chip such as an Insulated Gate Bipolar Transistor (IGBT), a diode, a Metal-Oxide-Semiconductor Field-Effect Transistor (MOSFET), or a Junction Field Effect Transistor (JFET) and is used to drive a power converting device such as an inverter, a converter, or an on board charger (OBC) that converts or controls power by using the semiconductor chip mentioned above.

Also, the bonding members 131 and 132 may contain at least any one of Ag, Cu, and Sn so as to have excellent electrical conductivity and thicknesses of the bonding members 131 and 132 may each be 10 μm through 500 μm.

Next, the electrical connecting member 140 may be formed to function as a spacer to maintain a vertical joint distance between the first substrate 110 and the second substrate 120 by being bonded to the semiconductor chip 130 of the first substrate 110 or the second substrate 120 or without being bonded to the semiconductor chip 130. Also, the electrical connecting member 140 is bent in a specific form to have elasticity. Accordingly, the electrical connecting member 140 may absorb push stress and thermal expansion stress or may disperse push stress and thermal expansion stress left and right or up and down, wherein the push stress and the thermal expansion stress are generated by a mold (not illustrated) while the package housing 150 is molded, the push stress is applied in a vertical direction toward the first substrate 110, the second substrate 120, and the semiconductor chip 130 and the thermal expansion stress is applied to the first substrate 110, the second substrate 120, and the semiconductor chip 130. In this regard, the semiconductor chip 130 may not be directly shocked and thereby, durability of the semiconductor chip 130 may be improved.

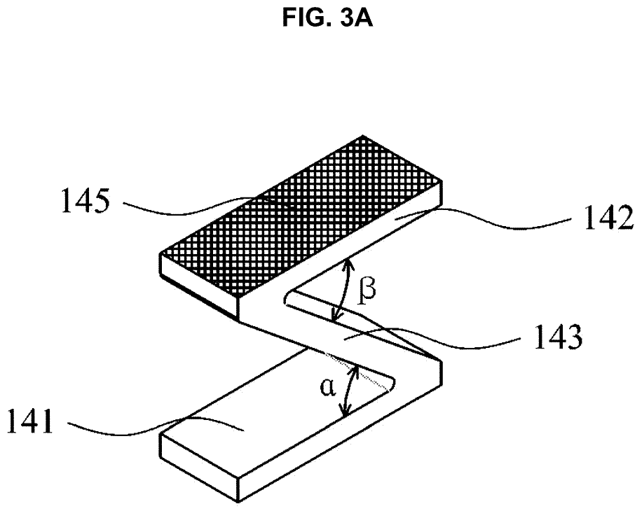

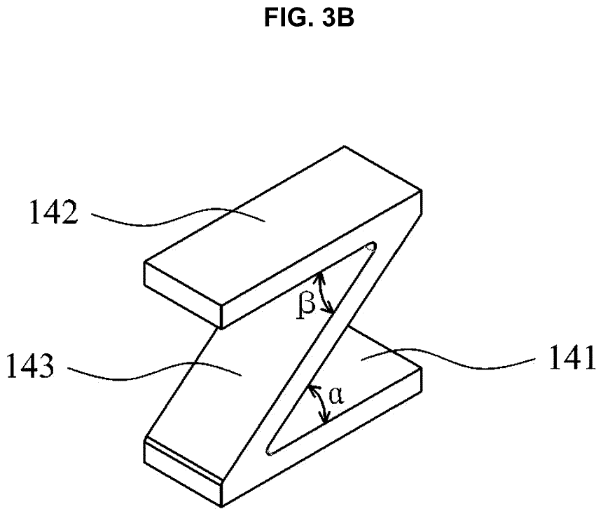

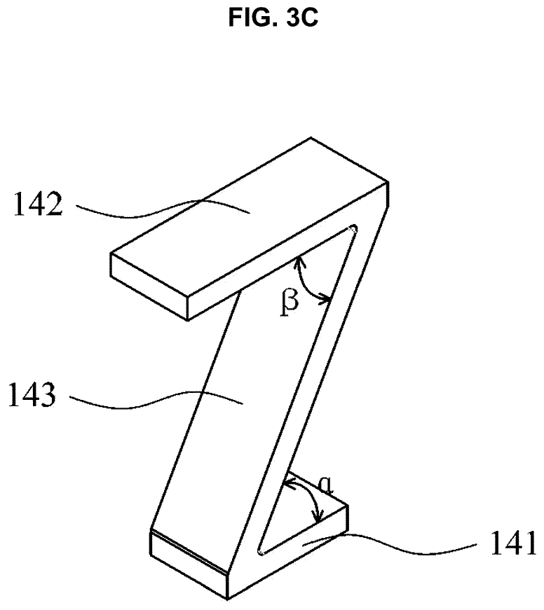

More specifically, referring to FIGS. 2 and 3A, 3B and 3C, the electrical connecting member 140 includes the first metal piece 141 formed in a straight line, the second metal piece 142 which faces the first metal piece 141 and is formed in a straight line, and the third metal piece 143 which is extended by being bent from one side of the first metal piece 141 to the other end of the second metal piece 142 and is combined to the first metal piece 141 and the second metal piece 142. The first acute angle α between the first metal piece 141 and the third metal piece 143 and the second acute angle β between the third metal piece 143 and the second metal piece 142 are each bent to incline by 1° through 85° according to a vertical separation distance between the first substrate 110 and the second substrate 120 or a bonding area of the first metal piece 141 and the second metal piece 142. Accordingly, the electrical connecting member 140 may disperse or absorb the push stress in a vertical direction and thermal expansion stress.

For example, the electrical connecting member 140 may be formed to have various structures in such a way that the third metal piece 143 of the electrical connecting member 140 may be structurally connected to the right end part of the first metal piece 141 and the left end part of the second metal piece 142 as illustrated in FIG. 3A or the third metal piece 143 of the electrical connecting member 140 may be structurally connected to the left end part of the first metal piece 141 and the right end part of the second metal piece 142 as illustrated in FIG. 3B.

Also, as illustrated in FIGS. 3A, 3B, and 3C, the third metal piece 143 is structurally connected between the first metal piece 141 and the second metal piece 142 in a diagonal direction to form in a z-letter shape. Accordingly, one or more electrical connecting members 140 may be structurally connected to the first substrate 110 and the second substrate 120.

Here, the first metal piece 141 is bonded to the other surface of the semiconductor chip 130 by using the conductive or non-conductive bonding member 132 interposed therebetween and the second metal piece 142 is bonded to the first substrate 110 or the second substrate 120 by using a conductive or non-conductive bonding member 144 interposed therebetween.

Meanwhile, the electrical connecting member 140 may be structurally connected to the first substrate 110 and/or the second substrate 120 by using the conductive bonding members 132 and 144 or may be directly bonded to the first substrate 110 and/or the second substrate 120 by ultrasonic welding without using any bonding members.

According to such structure of the electrical connecting member 140, the push stress in a vertical direction generated by a mold may be diverged from the semiconductor chip 130 by the third metal piece 143 and may be dispersed.

A thickness of the electrical connecting member 140, that is, each thickness of the first metal piece 141, the second metal piece 142, and the third metal piece 143 may be 0.1 mm through 1.5 mm, and thermal conductivity is 150 W/(m-k) through 550 W/(m-k). Accordingly, the electrical connecting member 140 may have excellent heat emission characteristic through the package housing 150 or the first and second substrates 110 and 120 exposed to the outside of the package housing 150.

Also, the electrical connecting member 140 contains at least copper component and thereby, has excellent ductility and malleability characteristics so that the electrical connecting member 140 may efficiently disperse push stress or thermal expansion stress and may have excellent electrical conductivity.

Meanwhile, although not illustrated, the electrical connecting member 140 may be or may not be bonded to the upper surfaces of one or more semiconductor chips 130 and may be extended and exposed to the outside of the package housing 150 so that the electrical connecting member 140 may function as not only a spacer but also a terminal device or heat emission.

In addition, a thickness of the first metal piece 141 included in the copper based or aluminum based electrical connecting member 140 bonded to the semiconductor chip 130 is greater than the thickness of the ceramic based insulating layers 112 and 122 of the first substrate 110 or the second substrate 120. In this regard, the metal pieces are formed to be thick and the insulating layers are formed to be thin so that generated heat may be efficiently transmitted to the outside while the semiconductor chips 130 are operated.

Furthermore, referring to FIG. 3A, opposed surfaces of the electrical connecting member 140 which are respectively bonded to the bonding members 132 and 144 may include a fine engraved pattern 145 having various forms thereon by using laser processing and bonding areas of the bonding members 132 and 144 and surface roughness increase to raise bond strength so that adhesive strength may be maintained even under the push stress above a certain size or the thermal stress.

Here, although not illustrated, the bonding members 132 and 144 may include metal grains of metal powder, wherein at least one metal grain may be electrically connected to the inner surface of the engraved pattern. An intermetallic compound (IMC) containing Sn having a semiconductor characteristic may be formed between a conductive adhesive, which is filled in the engraved pattern, and the inner surface of the engraved pattern or an IMC containing Cu having a semiconductor characteristic may be formed between the conductive adhesive and the inner surface of the engraved pattern. Also, metal projections having a certain height may be protruded in the inner surface of the engraved pattern having various structures and thereby, bond strength with the conductive adhesive may be increased.

FIGS. 8A and 8B illustrate a modification example of the electrical connecting member 140 of FIGS. 3A, 3B and 3C. Referring to FIGS. 8A and 8B, a first reinforcement bar 146 and a second reinforcement bar 147 are formed to reinforce an elastic force, wherein the first reinforcement bar 146 is extended from the upper surface of the first metal piece 141 to the bottom surface of the third metal piece 143 and has a semicircle structure and the second reinforcement bar 147 is extended from the bottom surface of the second metal piece 142 to the upper surface of the third metal piece 143 and has a semicircle structure. Accordingly, a z-letter form of the electrical connecting member 140 may not be easily deformed by an external force so that the separation distance between the first substrate 110 and the second substrate 120 may be stably maintained, the electrical connecting member 140 may be easily restored to an original state even if pressure is applied thereto by a mold, and heat radiation effect may be improved by an enlarged surface.

Next, the package housing 150 is molded to cover and protect the entire semiconductor chips 130 and at least a part of the electrical connecting member 140.

For example, the package housing 150 is formed of EMC, PBT, or PPS and insulates, covers and protects an internal circuit. A part of the terminal 160 is formed to be exposed to the outside of the package housing 150.

Next, each of one or more terminals 160 is electrically connected to the first substrate 110 or the second substrate 120 by using a conductive adhesive 161 interposed therebetween and a part of the terminal 160 is exposed to the outside of the package housing 150.

Also, one end of the terminal 160 may be selectively and electrically connected to the first substrate 110, the second substrate 120, or the first and second substrates 110 and 120 within the package housing 150.

As illustrated in FIG. 7, the first substrate 110, the second substrate 120, or at least a part of the first and second substrates 110 and 120 are exposed from the package housing 150 and surface contact with a cooling device so that heat generated while driving the semiconductor chip 130 may be radiated.

Also, one or more radiation fins 171 are arranged on the first substrate 110 or the second substrate 120 to be structurally exposed and thereby, cooling may be available using a coolant fluid by a water cooling method or using refrigerant gas by an air cooling method. The radiation fins 171 may be a conductor having heat transfer rate of 0.1 w/mk through 15 w/mk.

According to another embodiment of the present invention, a power converting device is provided, wherein the power converting device includes an inverter, a converter, or an on board charger that converts or controls power by using the semiconductor package described above.

Accordingly, in the semiconductor package described above, the push stress transferred to a mold while molding the package housing is dispersed or absorbed through the electrical connecting member having a non-vertical structure crossed in a specific angle and bent in a z-letter shape so that the semiconductor devices may be protected, bonded areas with the semiconductor devices may be prevented from being cracked, and thermal stress applied to the semiconductor chips and the substrates is dispersed or absorbed to minimize stress directly applied to the semiconductor devices.

According to the present invention, the push stress transferred to a mold while molding the package housing is dispersed or absorbed through the electrical connecting member having a non-vertical structure crossed in a specific angle and bent in a z-letter shape so that the semiconductor devices may be protected, bonded areas with the semiconductor devices may be prevented from being cracked, and thermal stress applied to the semiconductor chips and the substrates is dispersed or absorbed to minimize stress directly applied to the semiconductor devices.

Also, a high-priced metal spacer having a vertical structure which is formed of a material similar to a CTE of the semiconductor device may be replaced and thereby, price competitiveness of the semiconductor package may be increased.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
a first substrate comprising a specific metal pattern formed thereon to enable electrical connection;
a second substrate facing the first substrate which is spaced apart from the first substrate and comprises a specific metal pattern formed thereon to enable electrical connection;
at least one semiconductor chip in which one surface thereof is bonded to the first substrate, the second substrate, or the first and second substrates by using a first bonding member interposed therebetween;
at least one electrical connecting member comprising a first metal piece formed in a straight line, a second metal piece which faces the first metal piece and is formed in a straight line, and a third metal piece which is extended by being bent from one side of the first metal piece to the other end of the second metal piece and is combined to the first metal piece and the second metal piece, wherein the first metal piece is bonded to the other surface of the semiconductor chip by using a second bonding member interposed therebetween and the third metal piece is bonded to each of the second substrate, the first substrate, or the first and second substrates;
a package housing molded to cover the entire semiconductor chip and at least a part of the electrical connecting members; and
at least one terminal electrically connected to the first substrate or the second substrate and exposed to the outside of the package housing,
wherein a first acute angle between the first metal piece and the third metal piece and a second acute angle between the third metal piece and the second metal piece are each formed by being bent to be 1° through 85°.

2. The semiconductor package of claim 1, wherein the first substrate or the second substrate comprises at least one insulating layer.

3. The semiconductor package of claim 1, wherein the first substrate or the second substrate comprises a metal layer formed of a conductive metal material.

4. The semiconductor package of claim 1, wherein the first substrate or the second substrate comprises at least one metal layer, at least one insulating layer, and at least one metal layer which are stacked in order.

5. The semiconductor package of claim 3, wherein the metal layer of the first substrate or the second substrate bonded to the first bonding member has a thickness of 10 μm through 1.5 mm.

6. The semiconductor package of claim 1, wherein the electrical connecting member has a thickness of 0.1 mm through 1.5 mm.

7. The semiconductor package of claim 1, wherein the electrical connecting member has thermal conductivity of 150 W/(m-k) through 550 W/(m-k).

8. The semiconductor package of claim 1, wherein the electrical connecting member contains at least copper component.

9. The semiconductor package of claim 1, wherein the first bonding member or the second bonding member contains at least any one of Ag, Cu, and Sn.

10. The semiconductor package of claim 1, wherein the third metal piece of the electrical connecting member is structurally connected to the right end part of the first metal piece and the left end part of the second metal piece.

11. The semiconductor package of claim 1, wherein the third metal piece of the electrical connecting member is structurally connected to the left end part of the first metal piece and the right end part of the second metal piece.

12. The semiconductor package of claim 1, wherein the third metal piece of the electrical connecting member is structurally connected between the first metal piece and the second metal piece in a diagonal direction.

13. The semiconductor package of claim 1, further comprising additional electrical connecting members structurally connected to the first substrate and the second substrate.

14. The semiconductor package of claim 13, wherein the additional electrical connecting member is structurally connected to the first substrate and the second substrate by using a conductive bonding member or directly bonded to the first substrate and the second substrate by ultrasonic welding, or the additional electrical connecting member is structurally connected to the first substrate and the second substrate by using a conductive bonding member and directly bonded to the first substrate and the second substrate by ultrasonic welding.

15. The semiconductor package of claim 1, wherein one end of the terminal is electrically connected to each of the first substrate, the second substrate, or the first and second substrates within the package housing.

16. The semiconductor package of claim 1, wherein the first substrate, the second substrate, or at least a part of the first and second substrates is exposed from the package housing.

17. The semiconductor package of claim 1, wherein a thickness of the first metal piece in the electrical connecting member bonded to the semiconductor chip is greater than a thickness of the insulating layer of the first substrate or the second substrate.

18. The semiconductor package of claim 1, wherein at least any one of the first substrate and the second substrate comprises at least one radiation fin structurally exposed.

19. The semiconductor package of claim 1, wherein the semiconductor chip is an Insulated Gate Bipolar Transistor (IGBT), a diode, a Metal-Oxide-Semiconductor Field-Effect Transistor (MOSFET), or a Junction Field Effect Transistor (JFET).

20. A power converting device using the semiconductor package of claim 1.
